(19) United States
(12) Patent Application Publication
(10) Pub. No.: US 2026/0332103 A1
(43) Pub. Date: Oct. 22, 2026

(54) AI-BASED DIGITAL PREDISTORTION FOR DIGITAL DUAL-INPUT POWER AMPLIFIERS

(71) Applicant: Samsung Electronics Co., Ltd., Suwon-si (KR)

(72) Inventors: Matthew Tonnemacher, Allen, TX (US); Masoud Shahshahani, Allen, TX (US); Chance Anthony Tarver, Arlington, TX (US); Panagiotis Skrimponis, Dallas, TX (US); Gang Xu, Allen, TX (US)

(21) Appl. No.: 19/578,733

(22) Filed: Mar. 25, 2026

Related U.S. Application Data
(60) Provisional application No. 63/790,960, filed on Apr. 18, 2025.

(51) Int. Cl. H03F 1/32; H03F 3/24; H04B 1/04

(52) U.S. Cl. CPC H03F 1/3247; H03F 3/24; H04B 1/04; H03F 1/3282; H04B 2001/0425

(57) ABSTRACT

Apparatuses and methods for operating a power amplifier are provided. In some embodiments, the method includes receiving a first carrier signal and a first peaking signal, generating a first predistorted carrier signal by applying a first predistortion to the first carrier signal, and generating a first predistorted peaking signal by applying a second predistortion to the first peaking signal. The method further includes providing the first predistorted carrier signal to a first power amplifier and the first predistorted peaking signal to a second power amplifier, generating an amplified carrier signal using the first power amplifier, generating an amplified peaking signal using the second power amplifier, and combining the amplified carrier signal and the amplified peaking signal into an output signal.

### CROSS-REFERENCE TO RELATED APPLICATION AND CLAIM OF PRIORITY

This application claims priority under 35 U.S.C. § 119(e) to U.S. Provisional Patent Application No. 63/790,960 filed on Apr. 18, 2025. The above-identified provisional patent application is hereby incorporated by reference in its entirety.

### TECHNICAL FIELD

This disclosure relates generally to power amplifiers (PAs). More specifically, this disclosure relates to apparatuses and methods for adding predistortion is dual input power PAs.

### BACKGROUND

Power amplifiers (PAs) play a crucial role in modern mobile communication systems, especially in multiple-input multiple-output (MIMO) configurations, which contain a large quantity of PAs in a single base station. While it is convenient to model PAs as having a fixed gain, there is a nonlinear relationship between input and output power. As the input power increases, a fixed gain is not perfectly maintained. Digital predistortion (DPD) is one of the core techniques to compensate for PA nonlinearity, by applying a correction to the signal before transmission to account for the PA's nonlinear behavior.

### SUMMARY

This disclosure provides apparatuses and methods for operating a power amplifier.

In one embodiment, a method for operating a power amplifier is provided. The method includes receiving a first carrier signal and a first peaking signal, generating a first predistorted carrier signal by applying a first predistortion to the first carrier signal, and generating a first predistorted peaking signal by applying a second predistortion to the first peaking signal. The method further includes providing the first predistorted carrier signal to a first power amplifier and the first predistorted peaking signal to a second power amplifier, generating an amplified carrier signal using the first power amplifier, generating an amplified peaking signal using the second power amplifier, and combining the amplified carrier signal and the amplified peaking signal into an output signal.

In another embodiment, a power amplifier is provided. The power amplifier includes a first digital predistortion (DPD) circuitry configured to receive a first carrier signal and a first peaking signal, generate a first predistorted carrier signal by applying a first predistortion to the first carrier signal, and generate a first predistorted peaking signal by applying a second predistortion to the first peaking signal, wherein the first predistortion and second predistortion are generated by at least one artificial intelligence (AI) model. The power amplifier further includes a first power amplifier configured to receive the first predistorted carrier signal and generate an amplified carrier signal, a second power amplifier configured to receive the first predistorted peaking signal and generate an amplified peaking signal, and an output combiner circuitry configured to combine the amplified carrier signal and the amplified peaking signal into an output signal.

In another embodiment, a non-transitory computer readable medium include program code is provide that when executed by a power amplifier, causes the power amplifier to receive a first carrier signal and a first peaking signal, generate a first predistorted carrier signal by applying a first predistortion to the first carrier signal, and generate a first predistorted peaking signal by applying a second predistortion to the first peaking signal. The program code further causes the power amplifier to provide the first predistorted carrier signal to a first power amplifier and the first predistorted peaking signal to a second power amplifier, generate an amplified carrier signal using the first power amplifier, generate an amplified peaking signal using the second power amplifier, and combine the amplified carrier signal and the amplified peaking signal into an output signal.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of this disclosure and its advantages, reference is now made to the following description, taken in conjunction with the accompanying drawings, in which:

FIG. 1 illustrates an example wireless network according to embodiments of the present disclosure;

FIG. 2 illustrates an example BS according to embodiments of the present disclosure;

FIG. 3 illustrates an example of a UE according to embodiments of the present disclosure;

FIG. 4 illustrates an example power amplifier (PA) according to embodiments of the present disclosure;

FIG. 5 illustrates a flowchart for an example method for training a PA according to an embodiment of the present disclosure;

FIG. 6 illustrates an example artificial intelligence (AI) model according to embodiments of the present disclosure;

FIG. 7 illustrates an example PA according to embodiments of the present disclosure; and

FIG. 8 illustrates a flowchart for an example method for training a PA according to an embodiment of the present disclosure.

### DETAILED DESCRIPTION

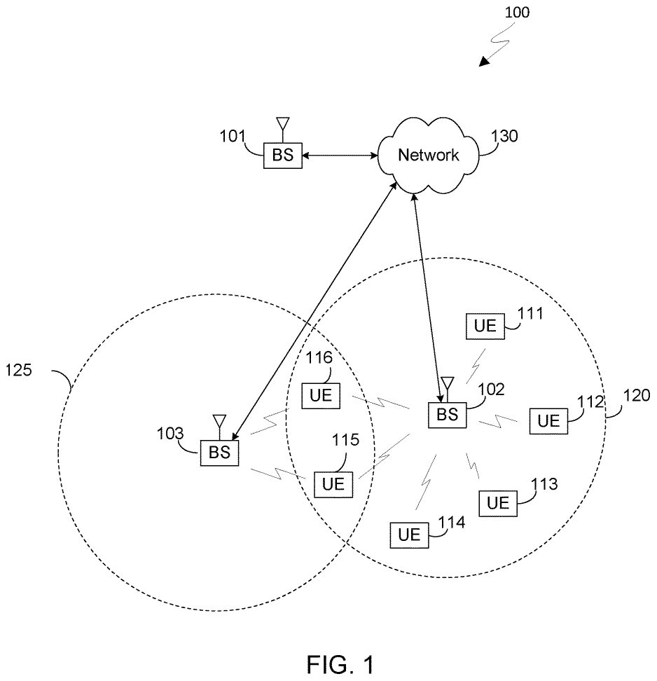

FIGS. 1-8, discussed below, and the various, non-limiting embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Power amplifiers (PAs) play an important role in modern mobile communication systems, especially in massive multiple-input multiple-output (MIMO) configurations, which contain a great number of PAs in a single base station (BS). Digital predistortion (DPD) is one of the core techniques to compensate for PA nonlinearity, by applying a correction to the signal before transmission to account for the PA's nonlinear behavior.

One PA technology is the Doherty amplifier, which is designed to achieve high power efficiency and linearity, particularly at high output levels. A Doherty amplifier includes two amplifiers: a carrier amplifier and a peaking amplifier. The carrier amplifier operates in Class AB mode, providing a constant output power level, while the peaking amplifier operates in Class C mode, providing additional power when needed. The two amplifiers are connected in parallel, with the output signal being a combination of the signals from both amplifiers. Typically, the peaking amplifier input is just a delayed version of the carrier input.

Dual drive power amplifiers (DDPAs) are similar to Doherty Amplifiers, but the carrier and peaking paths are freely controlled, usually by two digital input paths. By allowing free control over the relationship between carrier and peaking path signals, the DDPA can have improved power efficiency across multiple bands and even improve adjacent channel leakage ratio (ACLR) of the output signal for modulated waveforms. However, when developing a system with DDPAs, DPD design presents a significant design challenge. DDPAs have two separate amplifiers, each with its own unique characteristics and nonlinearities. Characterizing these amplifiers individually and then combining their responses to create an accurate DPD model can be challenging, especially when using other generalized memory polynomial (GMP) based models.

For example, the gain and phase mismatch between the carrier and peaking amplifiers can impact the accuracy of the DPD model. These mismatches can cause errors in the compensation process, leading to reduced linearity and increased distortion. Additionally, the load impedance seen by each amplifier in a DPA may vary depending on the operating conditions, which can affect the accuracy of the DPD model. This variability can make it difficult to create a single, accurate DPD model that works across all operating scenarios.

This disclosure relates to an artificial intelligence (AI) based digital predistortion model that inputs two signals derived from the original transmit signal, optimized for enhanced power efficiency, and jointly predistorts them to address the complexities of PA nonlinearity compensation in dual drive power amplifiers.

FIG. 1 illustrates an example wireless network according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or another data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the gNBs and/or one or more of the UEs 111-116 include an AI-based digital predistortion for power amplifiers, such as a DDPA.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

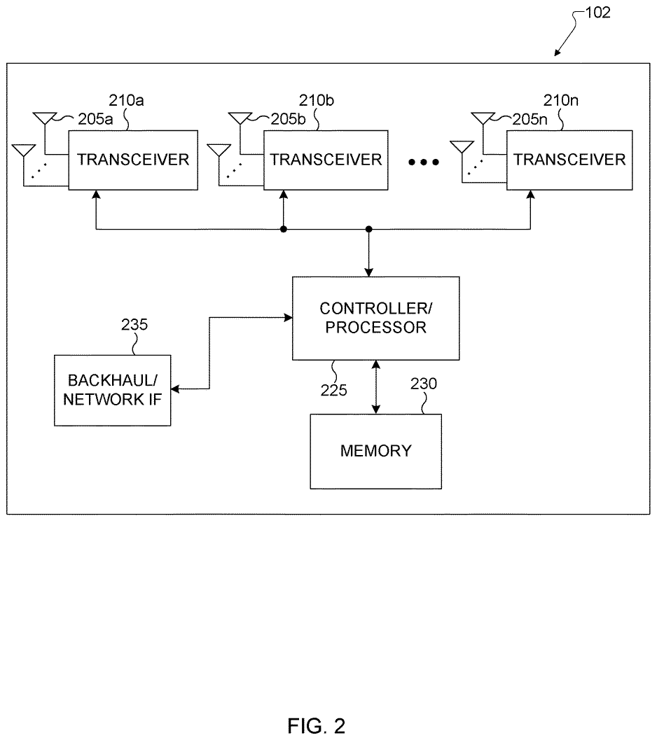

FIG. 2 illustrates an example gNB 102 according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming RF signals, such as signals transmitted by UEs in the network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the transmission of DL channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. Any of a wide variety of other functions could be supported in the gNB 102 by the controller/processor 225.

The controller/processor 225 is also capable of executing programs and other processes resident in the memory 230, such as processes for AI-based digital predistortion for power amplifiers as described in greater detail below. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

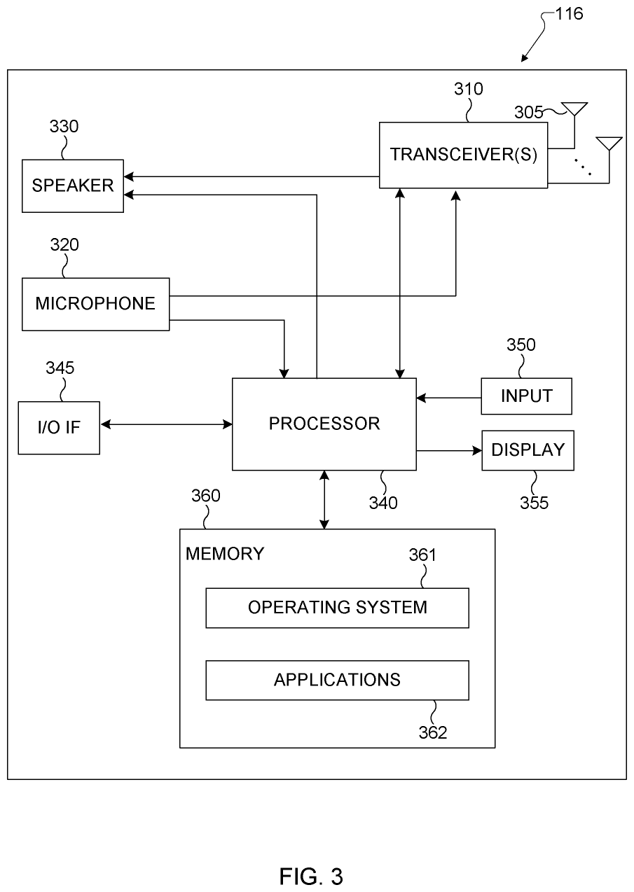

FIG. 3 illustrates an example UE 116 according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives from the antenna(s) 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals by the transceiver(s) 310 in accordance with well-known principles. In some embodiments, the processor 340 includes at least one microprocessor or microcontroller.

The processor 340 is also capable of executing other processes and programs resident in the memory 360. The processor 340 can move data into or out of the memory 360 as required by an executing process. For example, in various embodiments, the UE 116 uses AI-based digital predistortion.

In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350 and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

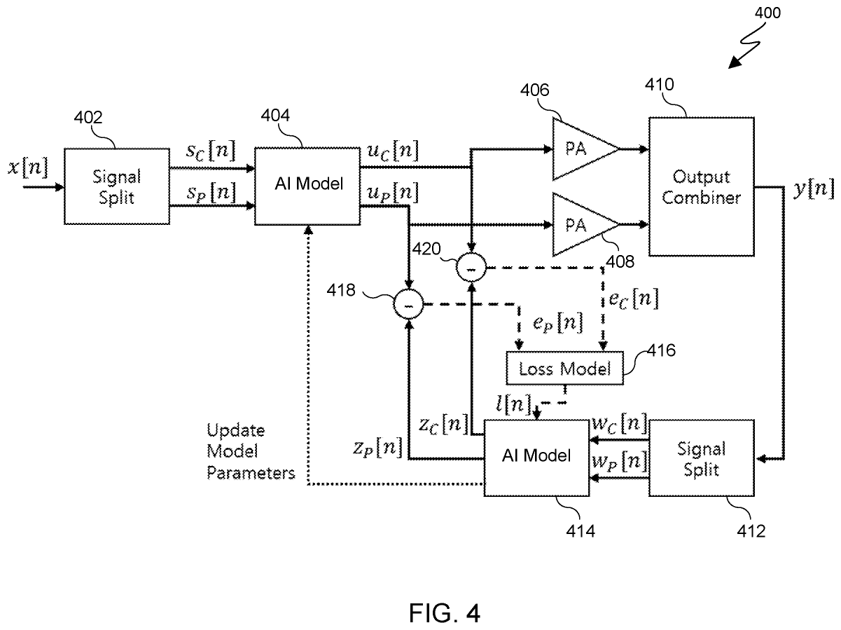

FIG. 4 illustrates an example PA 400 according to embodiments of the present disclosure. The embodiment of the PA 400 shown in FIG. 4 is for illustration only. Other embodiments of the PA 400 could be used without departing from the scope of this disclosure.

As shown in FIG. 4, in one or more embodiments, the PA 400 can be a DDPA. The PA 400 includes a signal split circuitry 402, a DPD circuitry 404, a carrier amplifier 406 (also referred to as a “first power amplifier”), a peaking amplifier 408 (also referred to as a “second power amplifier”), an output combiner circuitry 410, a signal split circuitry 412, a DPD circuitry 414, a loss model 416, a combinational circuitry 418, and a combinational circuitry 420.

In one or more embodiments, an input signal x[n] is provided to and received by the signal split circuitry 402. The input signal x[n] can be any suitable signal processed by the PA 400 such as a discrete transmit signal. The signal split circuitry 402 splits in the input signal x[n] into a first carrier signal s_{c}[n] and a first peaking signal sₚ[n]. The split signal circuitry 102 transmits the first carrier signal s_{c}[n] and a first peaking signal sₚ[n] to the DPD circuitry 404.

As noted above, to compensate for non-linearity in the PAs (the carrier amplifier 406 and the peaking amplifier 408), the DPD circuitry 404 is used to add corrections (predistortion) using at least one AI model. As shown in FIG. 1, the DPD circuitry 404 includes a single AI model. In other embodiments, the DPD circuitry 404 can include separate AI models to add corrections to the first carrier signal s_{c}[n] and a first peaking signal sₚ[n]. The DPD circuitry 404 receives both the first carrier signal s_{c}[n] and a first peaking signal sₚ[n] and adds predistortion, generating a first predistorted carrier signal u_{c}[n] and a first predistorted peaking signal uₚ[n]. The DPD circuitry 404 generates the first predistorted carrier signal u_{c}[n] by executing the AI model to add a first predistortion to the first carrier signal s_{c}[n] and generates the first predistorted peaking signal uₚ[n] by executing the AI model to add a second predistortion to the first peaking signal sₚ[n]. The first predistortion and the second predistortion can be the same or different.

However as noted above, because the PA 400 includes two different amplifiers there are challenges correcting both the first carrier signal s_{c}[n] and a first peaking signal sₚ[n] individually to account for the unique characteristics and non-linearities of both the carrier amplifier 406 the peaking amplifier 408. Advantageously, to combat this, the DPD circuitry includes and executes the AI model that is able to jointly predistort the first carrier signal s_{c}[n] and a first peaking signal sₚ[n] based on the non-linearity of the carrier amplifier 406 the peaking amplifier 408, respectively.

In one or more embodiments, the AI model include any suitable AI model that can jointly predistort the first carrier signal s_{c}[n] and the first peaking signal sₚ[n], such as a neural network (NN). The AI model can include any suitable type of NN including but not limited to, a feedforward NN, a convolutional NN (CNN), a recurrent NN (RNN), long short-term memory (LSTM) networks, or the like. An example NN is shown in more detail in FIG. 3 below.

Referring back to FIG. 1, the first predistorted carrier signal u_{c}[n] is provided to the carrier amplifier 406 and the first predistorted peaking signal uₚ[n] is provided to the peaking amplifier 408. The carrier amplifier 406 and the peaking amplifier 408 can be any suitable type of PA including, but not limited to, switched capacitor power amplifiers (SCPAs), voltage-mode amplifiers, or the like. The carrier amplifier 406 receives the first predistorted carrier signal u_{c}[n], generates an amplified carrier signal, and provides the amplified carrier signal to the output combiner circuitry 410. The peaking amplifier 408 receives the first predistorted peaking signal uₚ[n], generates an amplified peaking signal, and provides the amplified peaking signal to the output combiner circuitry 410. The output combiner circuitry 410 receives the amplified carrier signal and the amplified peaking signal and combines the amplified carrier signal and the amplified peaking signal into an output signal y[n].

One cycle of training the DPD circuitry 404 includes providing the output signal y[n] to the signal split circuitry 412. The signal split circuitry 412 splits the output signal into a second carrier signal w_{c}[n] and a second peaking signal wₚ[n]. The signal split circuitry 412 provides the second carrier signal w_{c}[n] and the second peaking signal wₚ[n] to the DPD circuitry 414. The DPD circuitry 414 includes the same type of AI model as the DPD circuitry 414. In one or more embodiments, as will be shown in more detail below, the DPD circuitry 414 can also include separate AI models.

The DPD circuitry 414 executes the AI model and outputs a second predistorted carrier signal z_{c}[n] and a second predistorted peaking signal zₚ[n]. The DPD circuitry 414 generates the second predistorted carrier signal z_{c}[n] by executing the AI model to add a third predistortion to the second carrier signal w_{c}[n] and generates the second predistorted peaking signal zₚ[n] by executing the AI model to add a second predistortion to the second peaking signal wₚ[n]. The third predistortion and the fourth predistortion can be the same or different. As will be described in more detail below, loss model 416 is used to train the AI model of the DPD circuitry 414 which is then used to update the AI model of the DPD circuitry 404.

At initialization, the DPD circuitry 404 and the DPD circuitry 414 include identical AI models. For example, if the AI model is a NN, initially, the AI models included in both DPD circuitry 404 and DPD circuitry 414 have the same coefficients (weights and/or biases). In each cycle, the DPD circuitry 414 is trained as an inverse of the PAs to compensate for nonlinearities. In one or more embodiments, the DPD circuitry 414 is trained by using the output in-phase and quadrature (I/Q) components for both the carrier amplifier 406 and the peaking amplifier 408 as inputs (the second carrier signal w_{c}[n] and a second peaking signal wₚ[n]) to the DPD circuitry 414 and the respective I/Q components for the carrier amplifier 406 and the peaking amplifier 408 as labels of the outputs (the second predistorted carrier signal z_{c}[n] and the second predistorted peaking signal zₚ[n]) of the DPD circuitry 414 (according to a given signal split function). Both the DPD circuitry 404 and the DPD circuitry 414 provide their respective inputs to the combinational circuitry 418 and the combinational circuitry 420. The DPD circuitry 404 provides the first predistorted peaking signal uₚ[n] to the combinational circuitry 418 and the first predistorted carrier signal u_{c}[n] to the combinational circuitry 420. The DPD circuitry 414 provides the second predistorted peaking signal zₚ[n] to the combinational circuitry 418 and the second predistorted carrier signal z_{c}[n] to the combinational circuitry 420.

The combinational circuitry 418 generates an estimated peaking output signal eₚ[n] based on a comparison of the first predistorted peaking signal uₚ[n] and the second predistorted peaking signal zₚ[n]. The combinational circuitry 420 generates an estimated carrier output signal e_{c}[n] based on a comparison of the first predistorted carrier signal u_{c}[n] and the second predistorted carrier signal z_{c}[n]. In one or more embodiments, the combinational circuitry 418 and the combinational circuitry 420 are subtractors. Thus, the estimated peaking output signal eₚ[n] is a differential signal generated by taking a difference between first predistorted peaking signal uₚ[n] and the second predistorted peaking signal zₚ[n]. Furthermore, the estimated carrier output signal e_{c}[n] is a differential signal generated by taking a difference between first predistorted carrier signal u_{c}[n] and the second predistorted carrier signal z_{c}[n]. The estimated peaking output signal eₚ[n] and the estimated carrier output signal e_{c}[n] are provided to the loss model 416 by the combinational circuitry 418 and the combinational circuitry 420, respectively. The estimated peaking output signal eₚ[n] and the estimated carrier output signal e_{c}[n] account for the non-linearities of the respective, PAs. Although the combinational circuitry 418 and the combinational circuitry 420 are described as subtractors this is for example purposes only. The combinational circuitry 418 and the combinational circuitry 420 can be any suitable type of combinational circuitry.

The loss model 416 generates and provides a loss model output signal l[n] to the DPD circuitry 414. The loss model output signal l[n] is generated as a function of a performance output metric including the predistorter output convergence, as well as ACLR, error vector magnitude (EVM), power-added efficiency (PAE), PA gain, or the like, depending on implementation needs. The DPD circuitry 414 coefficients (the AI model) are updated based on the loss model output signal l[n]. The DPD circuitry 414 then updates the DPD circuitry 404 coefficients (the AI model) to match coefficients.

By predistoring the first carrier signal s_{c}[n] and the first peaking signal sₚ[n] to generate the first predistorted carrier signal u_{c}[n], and the first predistorted peaking signal uₚ[n], respectively, using the AI model of the DPD circuitry 404, the first predistorted carrier signal u_{c}[n], and the first predistorted peaking signal uₚ[n], and the output signal y[n] are updated accordingly, and will be used to retrain the DPD circuitry 404 in a next cycle. In one or more embodiments, the quantity of training epochs per cycle should be chosen long enough such that the AI model coefficients completely converge.

As will be described in more detail below, in one or more embodiments, the AI model included in the DPD circuitry 404 is trained in one or more cycles (iterations). In one more embodiments, training is performed until the output signal y[n] meets a performance threshold metric. The performance threshold metric can include a threshold ACLR, EVM, PAE, PA gain, or the like. In other embodiments, training is performed until a difference determined by the combinational circuitry 418 and/or the combinational circuitry 420 each meet a respective threshold value.

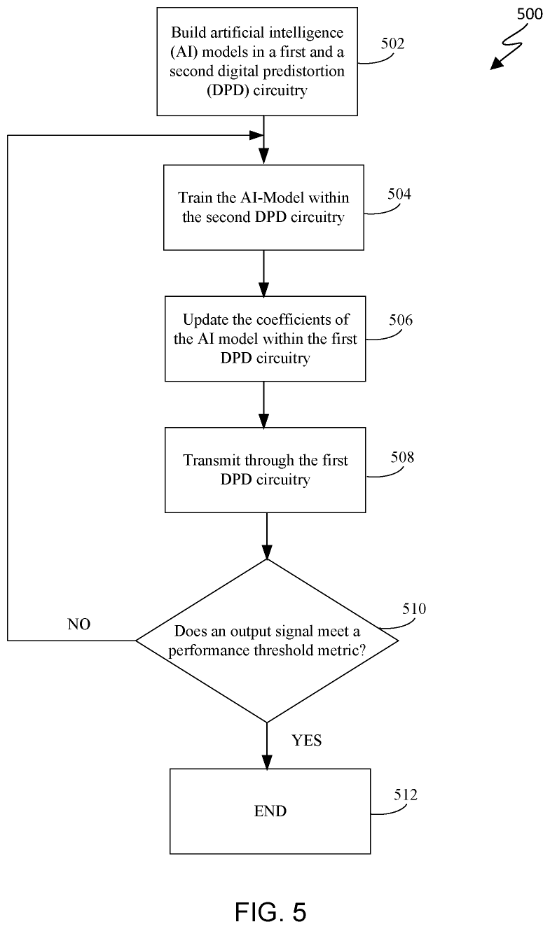

FIG. 5 illustrates a flowchart for an example method 500 for training a PA according to an embodiment of the present disclosure. For example, the method 500 can be performed by the PA 400.

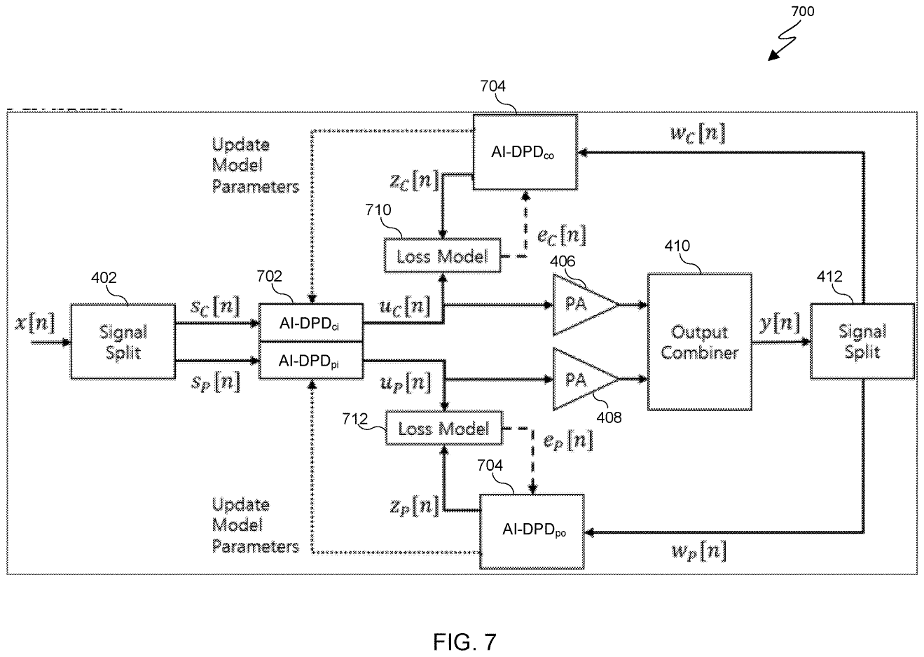

The method 500 begins with building the AI-models within the DPD circuitry 404 (first DPD circuitry) and the DPD circuitry 414 (second DPD circuitry) (202). As noted above, the AI-models are initially identical. Next, the AI-model within the DPD circuitry 414 is trained (504). As shown in FIG. 4, the training includes first splitting the input signal x[n] into the first carrier signal s_{c}[n] and the first peaking signal sₚ[n] using the signal split circuitry 402. The DPD circuitry 404 receives both the first carrier signal s_{c}[n] and the first peaking signal sₚ[n] and jointly adds predistortion, generating the first predistorted carrier signal u_{c}[n] and a first predistorted peaking signal uₚ[n]. Stated differently, the DPD circuitry 404 executes the AI model to add the first predistortion to the first carrier signal s_{c}[n] and the second predistortion to the first peaking signal sₚ[n]. In other embodiments, as shown in FIG. 7, the first predistortion can be added to the first carrier signal s_{c}[n] and the second predistortion can be added to the first peaking signal sₚ[n] by executing two separate AI models in parallel.

The first predistorted carrier signal u_{c}[n] is received by the carrier amplifier 406 and the first predistorted peaking signal uₚ[n] is received by the peaking amplifier 408. The carrier amplifier 406 generates the amplified carrier signal, and provides the amplified carrier signal to the output combiner circuitry 410. The peaking amplifier 408 generates the amplified peaking signal, and provides the amplified peaking signal to the output combiner circuitry 410. The output combiner circuitry 410 receives the amplified carrier signal and the amplified peaking signal, and combines the amplified carrier signal and the amplified peaking signal into an output signal y[n] and provides the output signal to the signal split circuitry 412. The signal split circuitry 412 splits the output signal into a second carrier signal w_{c}[n] and a second peaking signal wₚ[n] and provides the second carrier signal w_{c}[n] and the second peaking signal wₚ[n] to the DPD circuitry 414. The DPD circuitry 414 executes the AI model (same AI-model as the DPD circuitry 404) and outputs a second predistorted carrier signal z_{c}[n] and a second predistorted peaking signal zₚ[n]. Stated differently, the DPD circuitry 414 executes the AI model to add the third distortion to the second predistorted carrier signal z_{c}[n] and the fourth distortion the second predistorted peaking signal zₚ[n].

The second predistorted peaking signal zₚ[n] along with the first predistorted peaking signal uₚ[n] are provided to the combinational circuitry 418. The second predistorted carrier signal z_{c}[n] along with the first predistorted carrier signal u_{c}[n] are provided to the combinational circuitry 420. As described above, the combinational circuitry 418 generates estimated peaking output signal eₚ[n] and the combinational circuitry 420 generates an estimated carrier output signal e_{c}[n], which are provided to the loss model 416. The loss model 416 generates a loss model output signal l[n] based on the outputs of combinational circuitries 418, 420 that is used to train (update) the coefficients of the AI-model in the DPD circuitry 414.

Next, the DPD circuitry 414 then updates the coefficients of the AI-model in the DPD circuitry 404 (506) to match the coefficients between the DPD circuitries 404 and 414. In a next cycle, after updating the coefficients in the DPD circuitry 404, an output signal y[n] is generated, in the same manner described above, by transmitting through the DPD circuitry 404 (508). A performance output metric of the output signal y[n] is measured and is compared with a performance threshold metric (510). If the performance output metric of the output signal y[n] meets the performance threshold metric, training is complete (512). If the performance output metric of the output signal y[n] does not meet the performance threshold metric, the method 500 returns to step 504. For example, if the ACLR of the output signal y[n] is less than a threshold ACLR (does not meet a threshold ACLR), training continues until the ACLR of the output signal y[n] is greater than or equal to the threshold ACLR. Although FIG. 2 is described as continuing training until the ACLR is greater than or equal to the threshold ACLR (performance threshold metric), this is for example purposes only. Any suitable performance output metric including, but not limited to, EVM, PAE, PA gain, or predistorter output convergence can be used. The output signal y[n] can be trained until one or more of the performance output metrics meets a corresponding performance threshold metric (is greater than or equal to the performance threshold metric (or vice versa depending on the metric used)).

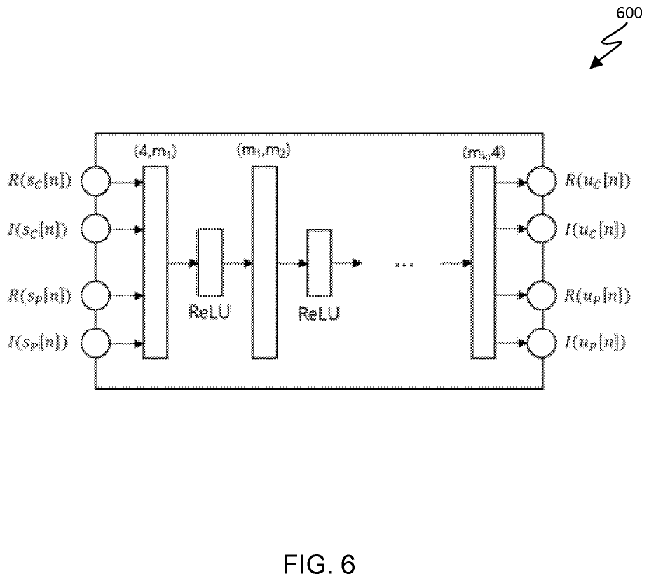

FIG. 6 illustrates an example AI model 600 according to embodiments of the present disclosure. In one or more embodiments, the AI model 600 is a fully-connected neural network is designed with four input neurons configured to receives, the real part, and the imaginary part of the first carrier signal s_{c}[n] and adds predistortion to the first carrier signal s_{c}[n] as inputs, while four output neurons respectively output the real part and the imaginary part of the first predistorted carrier signal u_{c}[n] and the first predistorted peaking signal uₚ[n]. At least one fully connected hidden layer is required. In one or more embodiments, a rectified linear unit (ReLU) is used as the activation function. However, using a ReLU activation function is for example purposes only. It is understood that any other suitable activation function can be used. Furthermore, the AI model be a more advanced neural network architectures can be, e.g., by adding time-adjacent signal I/Q components as input neurons, adding hidden layers, by applying a CNN, recurrent neural network RNN, LSTM networks, or the like.

As noted above, the DPD circuitry 404 and the DPD circuitry 414 include the same AI model and initially include the same coefficients. The loss model 416 is used to update the coefficients of the DPD circuitry 414 (AI model) which is then used to update the coefficients of the DPD circuitry 404 (AI model).

FIG. 7 illustrates an example PA 700 according to embodiments of the present disclosure. The embodiment of the PA 700 shown in FIG. 7 is for illustration only. Other embodiments of the PA 700 could be used without departing from the scope of this disclosure.

As shown in FIG. 7, in one or more embodiments, the PA 700 can be a DDPA. As noted above, in one or more embodiments, predistortion can be added to the first carrier signal s_{c}[n] and the first peaking signal sₚ[n]. As shown in FIG. 7, the PA 700 includes a DPD circuitry 702 that includes a carrier AI model (AI-DPD_{ci}) and a peaking AI model (AI-DPDₚᵢ). The DPD circuitry 702 receives the first carrier signal s_{c}[n] and executes AI-DPD_{ci} to add the first predistortion to the first carrier signal s_{c}[n], generating the first predistorted carrier signal u_{c}[n]. The DPD circuitry 702 receives the first peaking signal sₚ[n] and executes AI-DPDₚᵢ to add the second predistortion to the first peaking signal sₚ[n], generating the first predistorted peaking signal uₚ[n]. AI-DPD_{ci} and AI-DPDₚᵢ can be the same or different AI models. For example, AI-DPD_{ci} and AI-DPDₚᵢ can be identical (initially), can be the same type of AI model with different coefficients, or can be different types of AI models. The DPD circuitry 702 provides the first predistorted carrier signal u_{c}[n] to the carrier amplifier 406, and the first predistorted peaking signal uₚ[n] to the peaking amplifier 408.

The carrier amplifier 406 receives the first predistorted carrier signal u_{c}[n], generates an amplified carrier signal, and provides the amplified carrier signal to the output combiner circuitry 410. The peaking amplifier 408 receives the first predistorted peaking signal uₚ[n], generates an amplified peaking signal, and provides the amplified peaking signal to the output combiner circuitry 410. The output combiner circuitry 410 receives the amplified carrier signal and the amplified peaking signal and combines the amplified carrier signal and the amplified peaking signal into the output signal y[n].

The signal split circuitry 412 splits the output signal y[n] into the second carrier signal w_{c}[n] and the second peaking signal wₚ[n]. Because the DPD circuitry 702 includes 2 AI models, the PA 400 includes a DPD circuitry 704 that is also split into a carrier AI model (AI-DPD_{co}) and a peaking model and (AI-DPDₚₒ), and includes a loss model 710 and a loss model 712. As will be described in more detail below, the loss model 710 is used to train AI-DPD_{co} which is then used to update AI-DPD_{ci}. Additionally, the loss model 712 is used to train AI-DPDₚₒ which is then used to update AI-DPDₚᵢ.

At initialization, AI-DPD_{ci} and AI-DPD_{co} are identical AI models and AI-DPDₚᵢ and AI-DPDₚₒ are identical AI models. In the same manner described above, AI-DPD_{ci} adds the third predistortion and outputs the second predistorted carrier signal z_{c}[n], and AI-DPDₚₒ adds the fourth predistortion and outputs the second predistorted peaking signal zₚ[n].

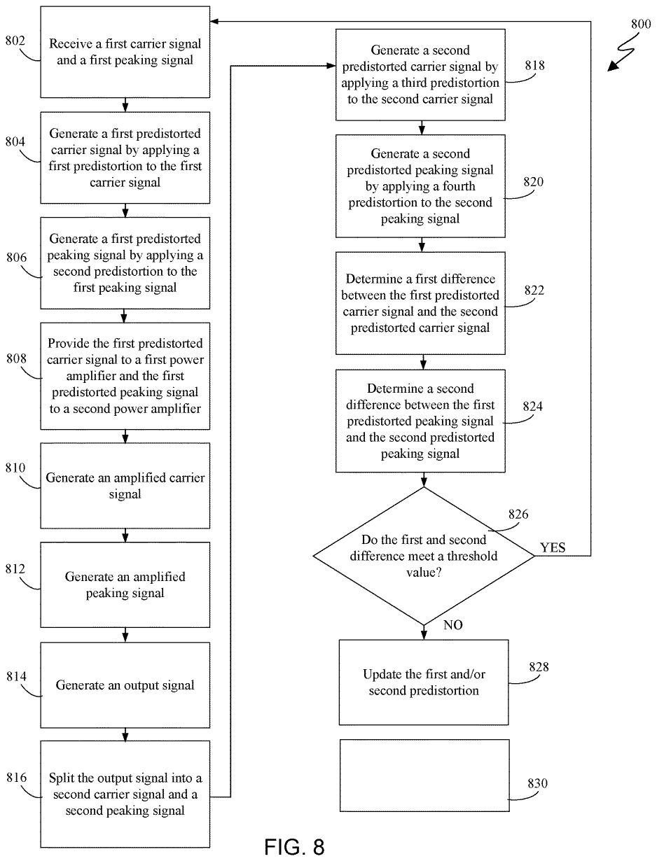

The second predistorted carrier signal z_{c}[n] is provided to the loss model 710. The second predistorted peaking signal zₚ[n] is provided to the loss model 712. The loss model 710 generates and provides the estimated carrier output signal e_{c}[n] to AI-DPD_{co} and is used to train (update) the AI-DPD_{co} coefficients. The loss model 712 generates and provides the estimated peaking output signal eₚ[n] to AI-DPDₚₒ which is used to train the AI-DPDₚₒ coefficients. AI-DPD_{co} updates the AI-DPD_{ci} coefficients to match coefficients. AI-DPDₚₒ also updates the AI-DPDₚᵢ coefficients to match coefficients. As noted above, in one embodiment, each of AI models are trained until the output signal y[n] meets a performance threshold metric. Stated differently, the steps of the method 500 can be performed by the PA 700 to train each of the AI models. In other embodiments, the AI models are trained until a difference determined by the combinational circuitry 418 and/or the combinational circuitry 420 (not shown in FIG. 7) each meet a threshold value. As described above, the second predistorted carrier signal z_{c}[n] and the estimated carrier output signal e_{c}[n] can be provided to the combinational circuitry 720 which can generate a signal that is provided to loss model 710 and is used to train AI-DPD_{co} (FIG. 8). Similarly, the second predistorted peaking signal zₚ[n] and the estimated peaking output signal eₚ[n] can be provided to the combinational circuitry 418 which can generate a signal that is provided to loss model 712 and is used to train AI-DPDₚₒ (FIG. 5).

FIG. 8 illustrates a flowchart for an example method 800 for training a PA according to an embodiment of the present disclosure. For example, the method 800 can be performed by the PA 400 (or the PA 700).

The method 800 begins with the DPD circuitry 404 receiving the first carrier signal s_{c}[n] and the first peaking signal sₚ[n] (802). The DPD circuitry 404 adds the first predistortion to the first carrier signal s_{c}[n], by implementing the AI-model, to the generate the first predistorted carrier signal u_{c}[n] (804). The DPD circuitry 404 adds the second predistortion to the first peaking signal sₚ[n], by implementing the AI-model, to the generate the first predistorted peaking signal uₚ[n] (806). As noted above, the first predistortion and the second predistortion can be the same or different predistortion and can be added jointly. Alternatively, the first predistorted carrier signal u_{c}[n] and the first predistorted peaking signal uₚ[n] can be generated (the first and second predistortion can be added) in parallel using multiple AI models (the method 800 can also be performed by PA 700).

Next, the first predistorted carrier signal u_{c}[n] is provided to (and received by) the carrier amplifier 406 and the first predistorted peaking signal uₚ[n] is provided to (and received by) the peaking amplifier 408 (808). The carrier amplifier 406 generates the amplified carrier signal (810). The peaking amplifier 408 generates the amplified peaking signal (812). The amplified carrier signal and the amplified peaking signal are combined into an output signal y[n] (814). The output combiner circuitry 410 receives the amplified carrier signal and the amplified peaking signal and combines them into the output signal y[n].

The output signal y[n] is split into the second carrier signal w_{c}[n] and the second peaking signal wₚ[n] (816). The signal split circuitry 412 receives and splits the output signal y[n] into the second carrier signal w_{c}[n] and the second peaking signal wₚ[n]. The DPD circuitry 414 adds the third distortion to the second carrier signal w_{c}[n] to generate the second predistorted carrier signal z_{c}[n] (818). The DPD circuitry 414 adds the fourth distortion to the second peaking signal wₚ[n] to generate the second predistorted peaking signal zₚ[n] (820). As noted above, the third predistortion and the fourth predistortion can be the same or different predistortion and can be added jointly. Alternatively, the third predistortion and the fourth predistortion can be added in parallel using multiple AI models (using the PA 700).

A first difference between the first predistorted carrier signal u_{c}[n] and the second predistorted carrier signal z_{c}[n] is determined (822). The first predistorted carrier signal u_{c}[n] and the second predistorted carrier signal z_{c}[n] are provided to the combinational circuitry 420 which determines the first difference. The combinational circuitry 420 generates the estimated carrier output signal e_{c}[n] based on the first difference. A second difference between the first predistorted peaking signal uₚ[n] and the second predistorted peaking signal zₚ[n] is determined (824). The first predistorted peaking signal uₚ[n]and the second predistorted peaking signal zₚ[n] are provided to the combinational circuitry 418 which determines the second difference. The combinational circuitry 418 generates an estimated peaking output signal eₚ[n] based on the second difference.

The first difference and the second difference are each compared to a threshold value (826). If either the first difference or the second difference is greater than the threshold value, the respective first predistortion and/or the second predistortion are updated (828). As noted above, the loss model 416 receives the estimated carrier output signal e_{c}[n] and the estimated peaking output signal eₚ[n] and generates the loss model output signal l[n] which is used to update the coefficients of the AI-model (the third and fourth predistortion) of the DPD circuitry 414. The DPD circuitry 414 then updates the coefficients of the AI-model of the DPD circuitry 404 (updates the first and second predistortion) and another cycle of training is performed (802-828). If the first difference and the second difference are less than the threshold value, training is complete (830). Alternatively, the first difference and second difference can be transmitted to different loss models that are used to update corresponding AI models in parallel (using the PA 700).

Advantageously, and as noted above, adding predistortion in a PA (such as a PA) using trained AI model(s) accounts for the gain and phase mismatch between the carrier and peaking amplifiers which improves the accuracy of the PA and allows for the formation of an accurate DPD circuitry that works across all operating scenarios.

Any of the above variation embodiments can be utilized independently or in combination with at least one other variation embodiment. The above flowcharts illustrate example methods that can be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claim scope. The scope of patented subject matter is defined by the claims.

What is claimed is:

1. A method for operating a power amplifier, the method comprising:
receiving a first carrier signal and a first peaking signal;
generating a first predistorted carrier signal by applying a first predistortion to the first carrier signal;
generating a first predistorted peaking signal by applying a second predistortion to the first peaking signal;
providing the first predistorted carrier signal to a first power amplifier and the first predistorted peaking signal to a second power amplifier;
generating an amplified carrier signal using the first power amplifier;
generating an amplified peaking signal using the second power amplifier; and
combining the amplified carrier signal and the amplified peaking signal into an output signal.

2. The method of claim 1, further comprising:
splitting the output signal into a second carrier signal and a second peaking signal;
generating a second predistorted carrier signal by adding a third predistortion to the second carrier signal;
generating, a second predistorted peaking signal by applying a fourth predistortion to the second peaking signal; and
determining a first difference between the first predistorted carrier signal and the second predistorted carrier signal and a second difference between the first predistorted peaking signal and the second predistorted peaking signal.

3. The method of claim 2, further comprising updating the first predistortion based on determining that the first difference is greater than a threshold value and updating the second predistortion based on determining that the second difference is greater than the threshold value.

4. The method of claim 2, further comprising updating the first predistortion based on determining that the first difference is greater than a threshold value.

5. The method of claim 2, further comprising updating the second predistortion based on determining that the second difference is greater than a threshold value.

6. The method of claim 1, wherein the first predistorted carrier signal and the first predistorted peaking signal are generated concurrently.

7. The method of claim 1, wherein the first predistorted carrier signal and the first predistorted peaking signal are generated in parallel.

8. A power amplifier comprising:
a first digital predistortion (DPD) circuitry configured to:
receive a first carrier signal and a first peaking signal,
generate a first predistorted carrier signal by applying a first predistortion to the first carrier signal, and
generate a first predistorted peaking signal by applying a second predistortion to the first peaking signal, wherein the first predistortion and second predistortion are generated by at least one artificial intelligence (AI) model,
a first power amplifier configured to receive the first predistorted carrier signal and generate an amplified carrier signal;
a second power amplifier configured to receive the first predistorted peaking signal and generate an amplified peaking signal; and
an output combiner circuitry configured to combine the amplified carrier signal and the amplified peaking signal into an output signal.

9. The power amplifier of claim 8, further comprising:
a split circuitry configured to receive the output signal and split the output signal into a second carrier signal and a second peaking signal;
a second DPD circuitry configured to:
generate a second predistorted carrier signal by adding a third predistortion to the second carrier signal, and
generate, a second predistorted peaking signal by applying a fourth predistortion to the second peaking signal, wherein the third predistortion and fourth predistortion are generated by at least one artificial intelligence (AI) model,
a first combinational circuitry configured to receive the first predistorted carrier signal and the second predistorted carrier signal and determine a first difference between the first predistorted carrier signal and the second predistorted carrier signal; and
a second combinational circuitry configured to receive the first predistorted peaking signal and the second predistorted peaking signal and determine a second difference between the first predistorted peaking signal and the second predistorted peaking signal.

10. The power amplifier of claim 9, further comprising a loss model to update the first predistortion and the second predistortion based on the first difference being greater than a threshold value and update the second predistortion based on the second difference being greater than the threshold value.

11. The power amplifier of claim 9, further comprising updating the first predistortion based on determining that the first difference is greater than a threshold value.

12. The power amplifier of claim 9, further comprising updating the second predistortion based on determining that the second difference is greater than a threshold value.

13. The power amplifier of claim 8, wherein the first predistorted carrier signal and the first predistorted peaking signal are generated by a single AI model or by different AI models.

14. A base station (BS) comprising the power amplifier of claim 8.

15. A non-transitory computer readable medium comprising program code that, when executed by a power amplifier, causes the power amplifier to:
receive a first carrier signal and a first peaking signal;
generate a first predistorted carrier signal by applying a first predistortion to the first carrier signal;
generate a first predistorted peaking signal by applying a second predistortion to the first peaking signal;
provide the first predistorted carrier signal to a first power amplifier and the first predistorted peaking signal to a second power amplifier;
generate an amplified carrier signal using the first power amplifier;
generate an amplified peaking signal using the second power amplifier; and
combine the amplified carrier signal and the amplified peaking signal into an output signal.

16. The non-transitory computer readable medium of claim 15, wherein the program code further causes the power amplifier to:
split the output signal into a second carrier signal and a second peaking signal;
generate a second predistorted carrier signal by adding a third predistortion to the second carrier signal;
generate a second predistorted peaking signal by applying a fourth predistortion to the second peaking signal; and
determine a first difference between the first predistorted carrier signal and the second predistorted carrier signal and a second difference between the first predistorted peaking signal and the second predistorted peaking signal.

17. The non-transitory computer readable medium of claim 16, wherein the program code further causes the power amplifier to update the first predistortion based on determining that the first difference is greater than a threshold value and update the second predistortion based on determining that the second difference is greater than the threshold value.

18. The non-transitory computer readable medium of claim 16, wherein the program code further causes the power amplifier to update the first predistortion based on determining that the first difference is greater than a threshold value.

19. The non-transitory computer readable medium of claim 16, wherein the program code further causes the power amplifier to update the second predistortion based on determining that the second difference is greater than a threshold value.

20. The non-transitory computer readable medium of claim 15, wherein the first predistorted carrier signal and the first predistorted peaking signal are generated concurrently or in parallel.
